(19) United States
(12) Patent Application Publication
(10) Pub. No.: US 2012/0062262 A1
(43) Pub. Date: Mar. 15, 2012

(54) Test Handlers For Semiconductor Packages and Test Methods Using the Same

(76) Inventor: Sang Jun Lee, Cheonan-si (KR)

(21) Appl. No.: 13/215,624

(22) Filed: Aug. 23, 2011

(30) Foreign Application Priority Data
Sep. 13, 2010 (KR) 10-2010-0089233

(51) Int. Cl. G01R 31/20

(52) U.S. Cl. 324/757.04

(57) ABSTRACT

A test handler for a semiconductor package includes a loader unit that is configured to transfer the semiconductor package to a test tray. A test chamber is configured to test the semiconductor package loaded in the test tray. An unloader unit is configured to remove the tested semiconductor package from the test tray. A loader stage is configured to convey the test tray from the unloader unit to the loader unit. A test tray cleaning unit proximate the loader stage is configured to clean the test tray while it is being conveyed from the unloader unit to the loader unit.

### CROSS-REFERENCE TO RELATED APPLICATIONS

This application claims the benefit of Korean Patent Application No. 10-2010-0089233, filed on Sep. 13, 2010, in the Korean Intellectual Property Office, the disclosure of which is incorporated herein in its entirety by reference.

### BACKGROUND

The inventive concept relates to a test handler for a semiconductor package and a test method using the same, and more particularly, to a test handler for a semiconductor package which may facilitate stable test contact so that test yield may be improved, and to a test method using the same.

Semiconductor integrated circuits existing on a semiconductor wafer in a chip state are generally processed into a package form to protect a chip from external shocks through a series of packaging processes. A processed semiconductor package generally needs to pass a package test process for performing an electrical function test (final test) before being delivered to a user. In the package test process, a tester having a computer with various measuring equipments and a handler for automatically transferring a semiconductor package to be connected to the test, which are referred to as a test handler, are generally used.

The package test process is to check reliability of a semiconductor packages and typically includes an electrical property test and a burn-in test. In the electrical property test, electrical properties, such as an input/output property, a pulse property, or noise allowance error, are tested. In a typical burn-in test, the device is checked to determine whether a problem is generated when a voltage higher than a regular voltage is applied for a predetermined time in an environment in which a temperature is higher than that of a normal operation environment.

To perform the reliability test for semiconductor packages, the semiconductor packages generally need to be electrically smoothly connected to a tester for testing the semiconductor packages. To this end, the semiconductor packages each may be transferred by being loaded in an insert that is installed on a test tray and thus electrically connected to a test socket connected to the tester.

In the test handler, however, after unloading the semiconductor package following completion of a test, the test tray is generally circulated to load a new semiconductor package to be tested. As the test process is performed with the circulation of a test tray, foreign materials, such as dust in the test handler and air or debris, may be accumulated in the insert of the test tray.

Nonetheless, in a conventional test handler, the foreign materials such as dust or debris existing in the insert of the test tray, may not be removed during the operation of the test handler. In order to remove the foreign materials from the insert of the test tray, the operation equipment generally needs to be halted and checked. Thus, the process is delayed and test yield may be deteriorated.

### SUMMARY

Some embodiments provide a test handler for a semiconductor package includes a loader unit that is configured to transfer the semiconductor package to a test tray. A test chamber is configured to test the semiconductor package loaded in the test tray. An unloader unit is configured to remove the tested semiconductor package from the test tray. A loader stage is configured to convey the test tray from the unloader unit to the loader unit. A test tray cleaning unit proximate the loader stage is configured to clean the test tray while it is being conveyed from the unloader unit to the loader unit.

In other embodiments, the test tray cleaning unit is a suction unit that pulls foreign materials from the test tray when the test tray is proximate the suction unit while being conveyed from the unloader unit to the loader unit. The suction unit may be a Coanda suction dust collector.

In further embodiments, the Coanda suction dust collector includes a compressed air inlet configured to be coupled to a compressed air source. A suction inlet is positioned proximate the test tray when the test tray is proximate the test tray cleaning unit. An air flow path has a start end coupled to the compressed air source by the compressed air inlet and coupled to the suction inlet and an opposite, exit end. The air flow path is configured to provide an air flow rate at the exit end exceeding an air flow rate of compressed air from the compressed air source at the start end using the Coanda effect. The air flow rate at the exit end may be at least twenty times the air flow rate of compressed air from the compressed air source at the start end to provide a suction air flow rate of at least nineteen times the air flow rate of compressed air from the compressed air source at the start end through the suction inlet.

In other embodiments, the Coanda suction dust collector further includes a collection body configured to collect foreign materials dropped from air passing through the air flow path and a filter portion at the exit end of the air flow path configured to remove foreign materials from air passing through the air flow path that are not collected in the collection body. The test handler may further include an ionizer proximate the loader stage that is configured to limit generation of static electricity between the semiconductor package and the test tray when the semiconductor package is in the test tray.

In yet further embodiments, the semiconductor package is a plurality of semiconductor packages. The test tray includes a plurality of inserts, each of which is configured to receive one of the plurality of semiconductor packages. The loader unit is configured to transfer each of the plurality of semiconductor packages into a corresponding one of the plurality of inserts. The suction inlet of the dust collector may be a plurality of openings separated from each other by a distance selected to correspond to a distance between respective ones of the plurality of openings of the suction inlet.

In other embodiments, the test tray cleaning unit is an an ionizer.

In further embodiments, the test handler further includes a soak chamber and an exit chamber. The soak chamber is proximate the test chamber and is configured to bring the temperature of the test tray to a first temperature before the test tray is conveyed to the test chamber. The exit chamber is proximate the test chamber and is configured to bring the test tray to a second temperature after the test tray is conveyed from the test chamber and before the test tray is conveyed from the unloader unit to the loader unit by the loader stage. The loader stage is configured to receive the test tray from the exit chamber and to convey the test tray to the soak chamber.

In yet other embodiments, a method of testing a semiconductor package includes unloading tested semiconductor packages from a test tray after the test tray is conveyed from a test chamber. The unloaded test tray is conveyed to a loader unit and automatically cleaned while it is being conveyed to the loader unit. The cleaned test tray is located with semiconductor packages to be tested in the test chamber after the cleaned test tray is conveyed to the loader unit. Automatically cleaning the unloaded test tray may include automatically cleaning the unloaded test tray using a Coanda suction dust collector that pulls foreign materials from the test tray when the test tray is proximate the Coanda suction dust collector while being conveyed to the loader unit.

In some embodiments, a test handler for a semiconductor package may facilitate stable test contact so that test yield and productivity may be improved, and a test method using the same is provided.

According to an aspect of the inventive concept, there is provided a test handler for a semiconductor package which includes a main body, a test chamber which is provided in the main body and tests a semiconductor package loaded in a test tray, and a test tray cleaning unit which is provided in the main body and cleans the test tray entering the test chamber or exiting from the test chamber.

The test tray cleaning unit may be provided close to at least one of areas of a movement path of the test tray that circulates for entering or exiting from the test chamber.

The test handler may further includes a soak chamber which is arranged close to the test chamber and preheats or pre-cools the semiconductor package, and an exit chamber which is arranged close to the test chamber and returns the semiconductor package to a room temperature state, wherein the test tray cleaning unit is arranged between a loader stage where the test tray is located before entering the soak chamber and an unloader stage where the test tray is located after exiting from the exit chamber and before being transferred to the loader stage.

The test tray cleaning unit may be a suction dust collector that sucks foreign materials existing in an insert of the test tray.

The test tray cleaning unit may be a Coanda suction dust collector that sucks foreign materials existing in an insert of the test tray by utilizing a Coanda effect in which a fluid flows in a direction in which the least amount of energy is consumed.

The Coanda suction dust collector may include a blow portion which blows air to the outside, a cover which is coupled to the blow portion and includes a plurality of through holes formed therein, a collection portion which collects foreign materials sucked from the test tray, and a support portion which supports the blow portion, the cover, and the collection portion.

The blow portion may include a first blow body in which a main air path is formed, a second blow body which is coupled to the first blow body and forms an exit air path, and an air supply pipe which is coupled to the first blow body and supplies air to the main air path.

The collection portion may include a collection body, a collection basket which is coupled to the collection body and forms an accommodation space for accommodating foreign materials, and a filter portion which is coupled to the collection body and filters exiting air.

The test tray cleaning unit may further include an ionizer which is coupled to the main body between the exiting chamber and the loader stage and blows air to prevent generation of static electricity due to friction between the semiconductor package and the insert of the test tray.

The test tray cleaning unit may be an ionizer which is coupled to the main body and blows air to prevent generation of static electricity due to friction between the semiconductor package and the insert of the test tray.

According to another aspect of the inventive concept, there is provided a method of testing a semiconductor package which includes cleaning a test tray in which a semiconductor package to be tested is loaded, and testing the semiconductor package loaded in the test tray.

The method may further include loading the semiconductor package in the test tray after cleaning the test tray, and unloading the semiconductor package that completed a test from the test tray.

The method may further include preheating or pre-cooling the semiconductor package before testing the semiconductor package, and returning the semiconductor package to a room temperature state after the test is completed, wherein the cleaning of a test tray is removing of foreign materials existing in an insert of the test tray while the test tray is moved between a loader stage in which the test tray is arranged before entering a soak chamber and an unloader stage arranged before moving to the loader stage after exiting from the exit chamber.

The removing of the foreign materials may be sucking and removing the foreign materials of the test tray.

The removing of the foreign materials may be sucking the foreign materials existing in the insert of the test tray utilizing a Coanda effect in which a fluid flows in a direction in which the least amount of energy is consumed.

The method may further include blowing air to the test tray to prevent generation of static electricity due to friction between the semiconductor package and the insert of the test tray, before the unloading of the semiconductor package that completed a test from the test tray.

The cleaning of the test tray may be blowing air to the test tray to prevent generation of static electricity due to friction between the semiconductor package and the insert of the test tray.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic plan view of a test handler for a semiconductor package, according to some embodiments of the present inventive concept;

FIG. 2 is a plan view of a test tray used for a test handler for a semiconductor package, according to some embodiments of the present inventive concept;

FIGS. 3 and 4 are perspective views of an insert of the test tray of FIG. 2;

FIGS. 5 and 6 conceptually illustrate a state in which a test tray is being cleaned by a test tray cleaning unit of a test handler for a semiconductor package according to some embodiments of the present inventive concept;

FIGS. 7-9 are perspective views of a test tray cleaning unit of a test handler for a semiconductor package according to some embodiments of the present inventive concept;

FIG. 10 is an exploded perspective view of the test tray cleaning unit of FIG. 7;

FIG. 11 is a cross-sectional view of the test tray cleaning unit of FIG. 7;

FIGS. 12 and 13 are perspective views illustrating major parts of a blow unit of the test tray cleaning unit of FIG. 7;

FIG. 14 is a flowchart illustrating a method of testing a semiconductor package according to some embodiments of the present inventive concept;

FIG. 15 is a schematic plan view of a test handler for a semiconductor package according further embodiments of the present inventive concept; and

FIG. 16 is a schematic plan view of a test handler for a semiconductor package according to further embodiments of the present inventive concept.

### DETAILED DESCRIPTION OF THE EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

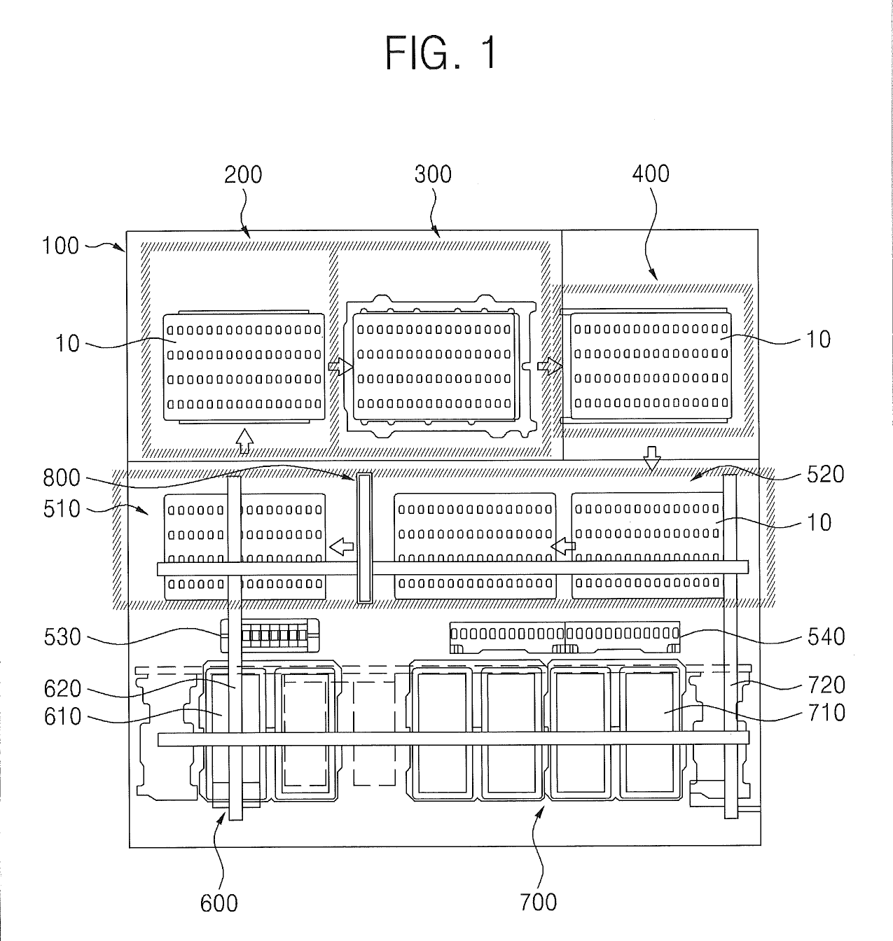

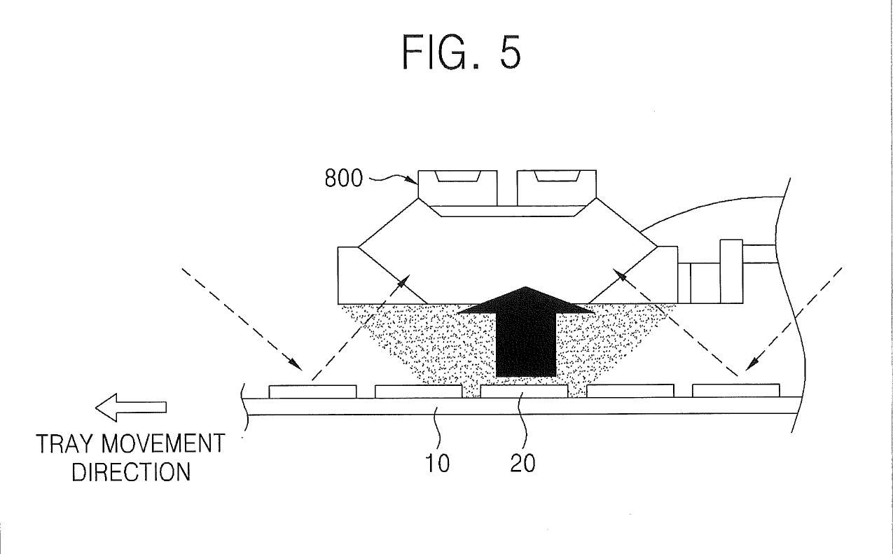

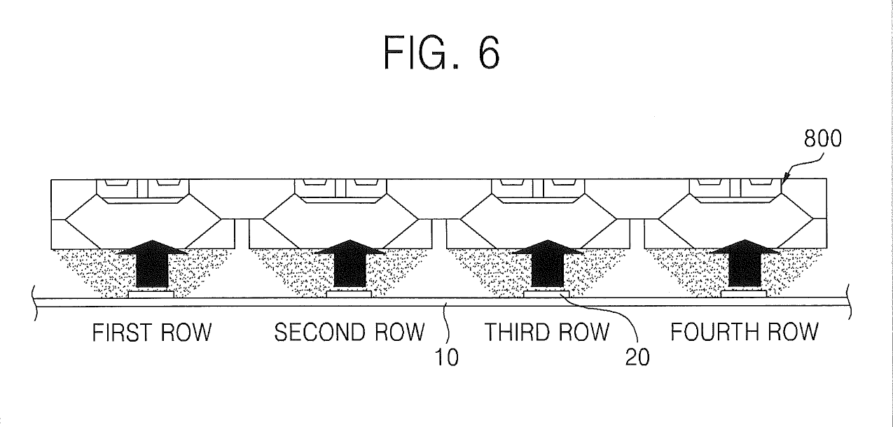

As illustrated in FIGS. 1-13, a test handler for a semiconductor package according to some embodiments includes a main body 100, a loader unit 600 for supplying a semiconductor package to be tested, an unloader unit 700 for unloading a semiconductor package that completed a test, a soak chamber 200 for pre-heating or pre-cooling a semiconductor package to a predetermined temperature, a test chamber 300 for testing the semiconductor package loaded on a test tray 10, an exit chamber 400 for returning the semiconductor package that completed a test to a room temperature state, and a test tray cleaning unit 800 for cleaning the test tray 10.

The loader unit 600, the unloader unit 700, the soak chamber 200, the test chamber 300, the exit chamber 400, and the test tray cleaning unit 800 are coupled to the main body 100, which serves as a frame supporting the coupled units.

The loader unit 600 includes a loading stocker, a loading side set plate 610, and a loader Cartesian robot 620. The loading stocker is provided in front of the main body 100 and loaded with a plurality of customer trays. Each of the customer trays is loaded with a plurality of semiconductor packages to be tested. The customer trays loaded in the loading stocker are sequentially transferred to the loading side set plate 610 by a transfer arm that is not shown. The loader Cartesian robot 620 includes a plurality of hands for sucking semiconductor packages. By reciprocating between the customer tray and the test tray 10, the loader Cartesian robot 620 transfers the semiconductor package to be tested that is loaded in the customer tray from the customer tray to the test tray 10.

The unloader unit 700, similarly to the loader unit 600, includes an unloading stocker, an unloading side set plate 710, and an unloader Cartesian robot 720. The unloading stocker is provided at one side portion of the loading stocker and the semiconductor packages that completed a test are classified according to a test result and loaded in the customer tray in the unloading stocker. The customer trays located at the unloading side set plate 710 are sequentially transferred to the unloading stocker by a transfer arm that is not shown. The unloader Cartesian robot 720 includes a plurality of hands for sucking semiconductor packages. By reciprocating between the customer tray and the test tray 10, the unloader Cartesian robot 720 transfers the semiconductor package that completed a test and loaded in the test tray 10 from the test tray 10 to the customer tray.

In summary, the loading stocker for loading a plurality of customer trays containing semiconductor packages to be tested and the unloading stocker for loading the customer tray containing the semiconductor packages that completed a test and sorted according to a grade are respectively arranged in front of the main body 100. The loading side set plate 610 and the unloading side set plate 710 that are waiting sites for loading and unloading of the semiconductor package are respectively arranged above the loading stocker and the unloading stocker.

The loader Cartesian robot 620 and the unloader Cartesian robot 720 include a plurality of hands for sucking the semiconductor packages and may be driven by a servo motor and a timing belt so as to continuously reciprocate between the customer trays and the test tray 10. Accordingly, the loader Cartesian robot 620 transfers a semiconductor package to be tested from the customer tray to the test tray 10, whereas the unloader Cartesian robot 720 transfers the semiconductor package that completed a test from the test tray 10 to the customer tray.

As shown by the arrows in FIG. 1, the test tray 10 in some embodiments sequentially moves and repeatedly circulates among a loader stage 510 that is a standby site before entering the soak chamber 200, the soak chamber 200, the test chamber 300, the exit chamber 400, and an unloader stage 520 that is a standby site before being transferred to the loader stage 510 after exiting from the exit chamber 400.

The test tray 10 is positioned in the loader stage 510 for loading a semiconductor package to be tested. The unloader stage 520 may have a classification site where the test tray 10 waits for classification of the semiconductor packages that completed a test and a buffer site where the test tray 10 waits to be moved into position to supply an empty test tray to the loader stage 510.

Also included in the circulation path of the test tray 10 of the test handler for some embodiments is a conveyer apparatus for circulating the test tray 10 among the loader stage 510, the soak chamber 200, the test chamber 300, the exit chamber 400, and the unloader stage 520, and a main controller for controlling the conveyer apparatus.

Also shown in the embodiments of FIG. 1 is a preciser 530 that is provided between the loader unit 600 and the loader stage 510. The semiconductor packages on the customer tray may be precised (oriented/aligned) in the preciser 530 by the loader Cartesian robot 620 so as to accurately match a position in the test tray 10. A buffer unit 540 may be provided between the unloader unit 700 and the unloader stage 520.

The soak chamber 200, the test chamber 300, and the exit chamber 400 are shown as provided in the rear portion of the main body 100 in FIG. 1.

The test tray 10 loaded with the semiconductor packages is moved from the soak chamber 200 toward the exit chamber 400. The soak chamber 200 in some embodiments is configured to preheat and/or pre-cool the test tray 10 loaded with the semiconductor packages to a predetermined temperature before being supplied to the test chamber 300. In addition, the exit chamber 400 may be configured to return the semiconductor package that completed the test in the test chamber 300 to the initial room temperature or other selected temperature state.

The test chamber 300 is configured to perform a test by electrically connecting each of the semiconductor packages loaded in the test tray 10 with a test socket of a test board by using, for example, a test plate. The test chamber 300 may be configured to do so while maintaining the test tray and semiconductor packages thereon at a selected high temperature or a lower temperature during testing.

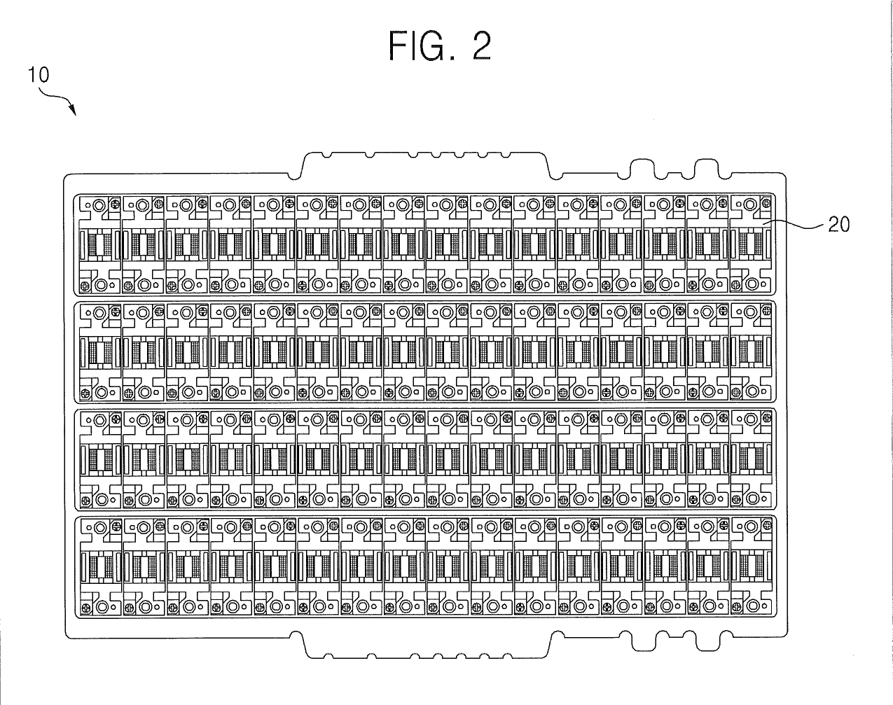

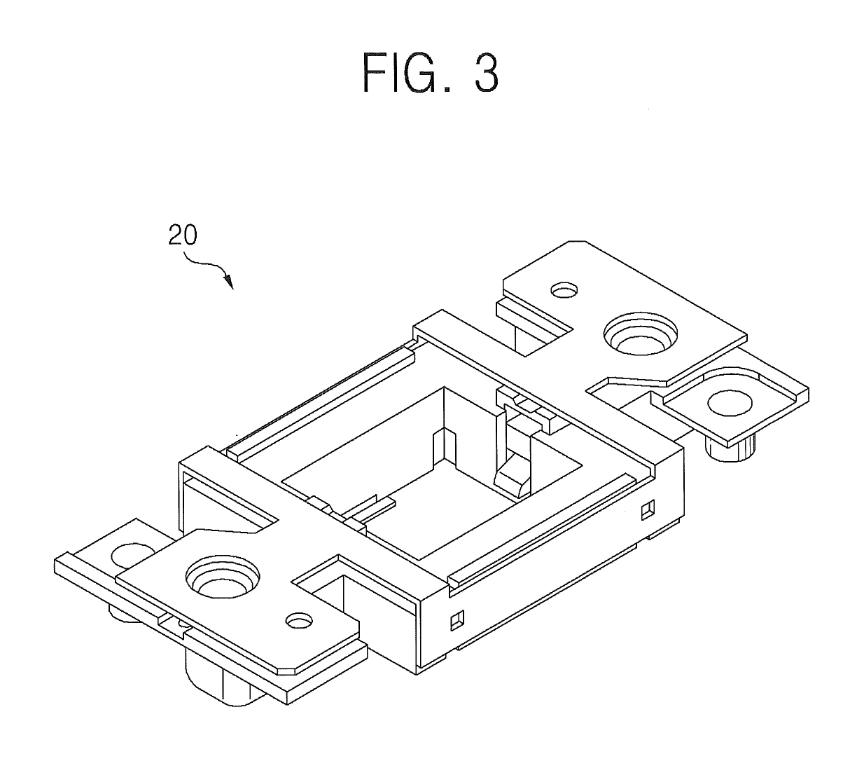

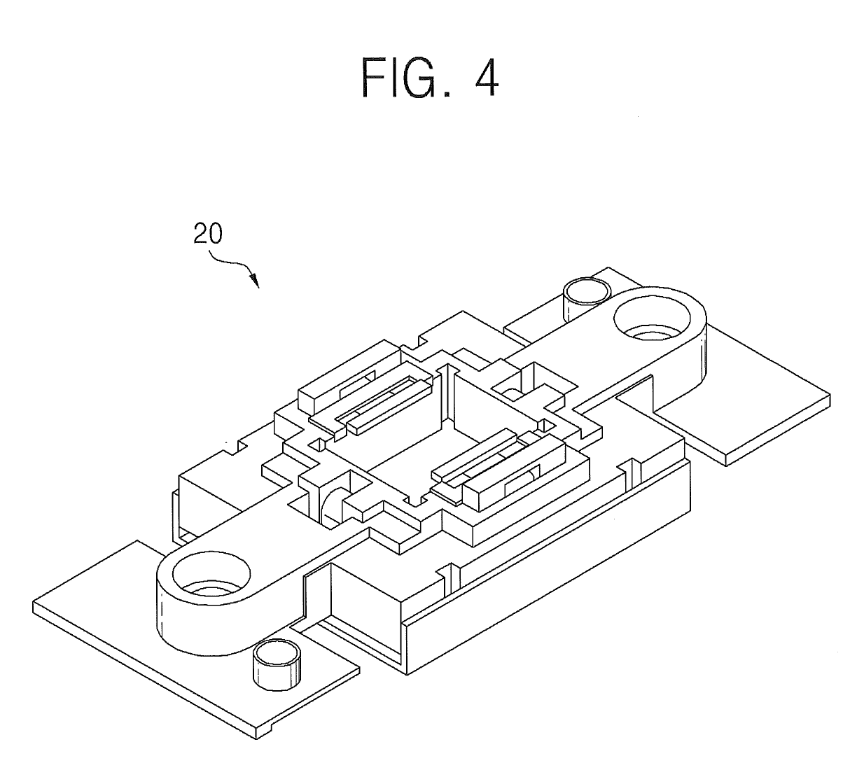

A test tray 10 according to some embodiments is further illustrated in FIG. 2. The test tray 10 of FIG. 2 includes a plurality of inserts 20. In practice, after a process of manufacturing a semiconductor package is completed, in some embodiments, the semiconductor package is transferred loaded in the insert 20. Some embodiments of an insert 20 are further illustrated in FIGS. 3 and 4. An electrical function thereof is then tested in the test chamber 300. The electrical function test may be performed by electrically connecting the semiconductor package, transferred loaded in the insert 20 installed on the test tray 10, to the test socket connected to a tester and analyzing a signal input to or output from each contact portion of the package using a test circuit.

Accordingly, the bottom of the insert 20 of the test tray 10 may be configured to act as a medium for mechanically coupling the semiconductor package and the tester. As such, it may be desireable to maintain the insert 20 of the test tray 10 in a clean condition. Also, in some embodiments, a rubber contactor is used for the contact of the semiconductor package in the insert 20.

As the test process is repeated, foreign materials, such as debris or dust, may be accumulated in the insert 20 of the test tray 10 that circulates among the loader stage 510, the soak chamber 200, the test chamber 300, the exit chamber 400, and the unloader stage 520. If the foreign materials are not appropriately removed, a quality problem and deterioration of yield may be generated. As a conventional test handler does not generally properly remove the foreign materials, such as debris or dust, from the insert 20 of the test tray 10 and has a structure that requires an operating equipment to be stopped for checking in order to remove the foreign materials from the insert 20 of the test tray 10, test yield and productivity deterioration may be generated as described above.

To address the above issue, the test handler according to some embodiments further includes the test tray cleaning unit 800 (FIG. 1) for cleaning the test tray 10. The test tray cleaning unit 800 according to some embodiments may facilitate stable test contact by removing the foreign materials, such as debris or dust, from the test tray 10.

That is, the test handler of some embodiments includes the test tray cleaning unit 800 that is installed on a circulation path of the test tray 10 and automatically cleans the inside of the insert 20 of the test tray 10.

As illustrated in FIGS. 1, 5, and 6, the test tray cleaning unit 800 of some embodiments is installed between the loader stage 510 and the unloader stage 520 to automatically clean the test tray 10 as it moves toward the loader stage 510 after unloading the semiconductor package that completed a test. The test tray cleaning unit 800 may be installed between the loader stage 510 and the unloader stage 520 as it is an area where cleaning of the test tray 10 may be efficiently performed to maximize the cleanliness of the test tray 10 before loading of the next package for testing. The cleaning may be automatically performed during the movement of the test tray 10 and, as such, the test process does not need to be stopped when the test tray 10 is cleaned.

Although the test tray cleaning unit 800 may be variously provided, the test tray cleaning unit 800 of some embodiments is a dust collector, in particular, a suction dust collector that sucks foreign materials existing in the test tray 10.

Although air may be blown toward the test tray 10 instead of sucking air around the test tray 10 to clean the test tray 10, as particles may be generated, a suction method of sucking foreign materials of the test tray 10 is used in some embodiments.

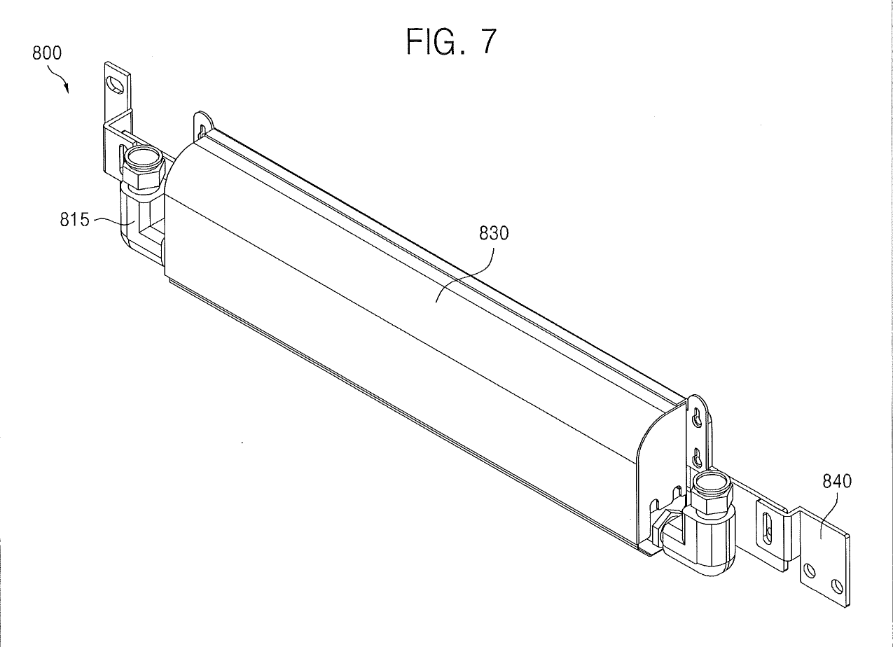

Also, as illustrated in FIGS. 7-13, the test tray cleaning unit 800 of some embodiment adopts a Coanda suction dust collector 800 having a structure of sucking foreign materials of the test tray 10 by using a Coanda effect to facilitate fluid flow. Although a method of vacuum sucking using a vacuum motor to suck foreign materials of the test tray 10 may be used, a vacuum suction method generally requires a space for installing a vacuum motor. In some embodiments, the Coanda suction dust collector 800 has a structure utilizing the Coanda effect and capable of sucking foreign materials from the test tray 10 without installing the vacuum motor, which may provide an installation space efficiency as developed and adopted.

When compressed air compressed by a compressor is supplied to the Coanda suction dust collector 800 according to some embodiments, a large amount of surrounding air 20 to 40 times larger than the compressed air may be sucked through the dust collector 800.

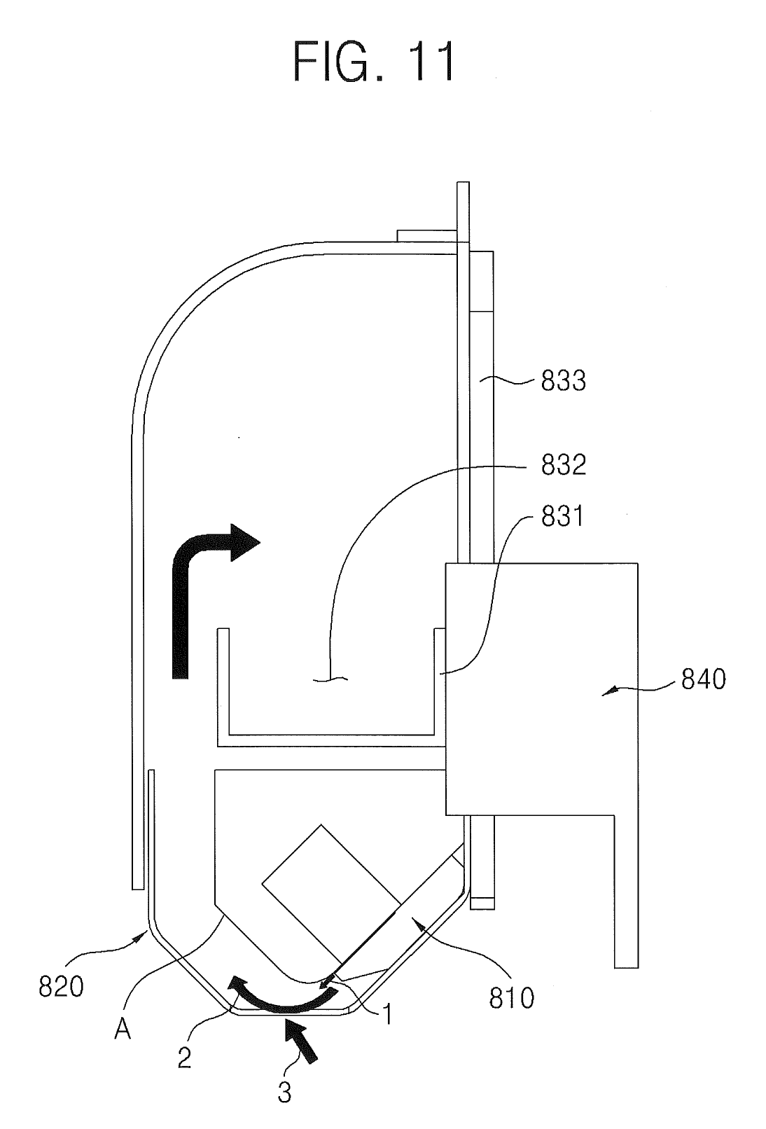

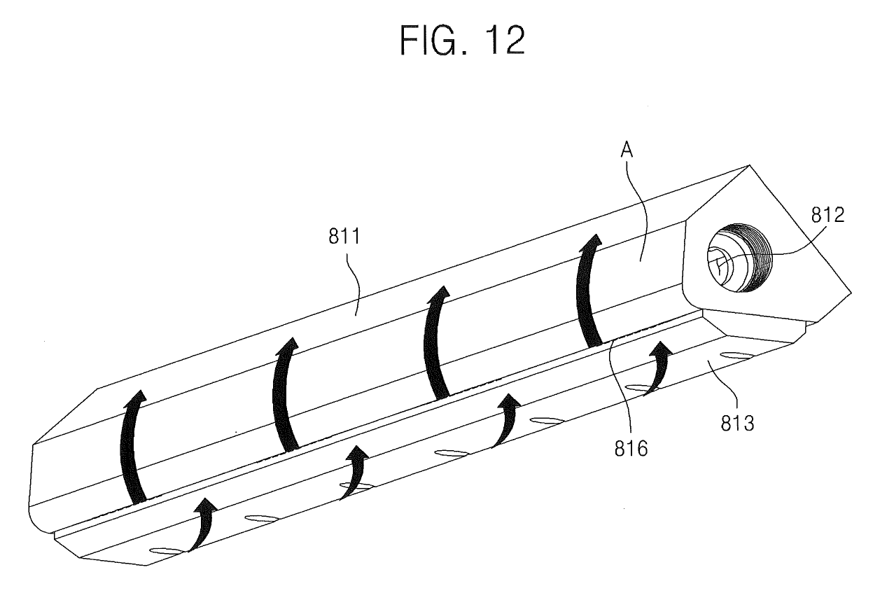

To briefly described the above principle, as illustrated in FIGS. 11 and 12, when air is exhausted along an exit air path 816 in a direction along an arrow 1, the air flow changes to flow along an inclined surface A as indicated by an arrow 2 so that the flow of surrounding air is formed as indicated by an arrow 3. Accordingly, vacuum is generated under the Coanda suction dust collector 800 so that the foreign materials existing in the insert 20 of the test tray 10 may be sucked upwardly due to a suction force.

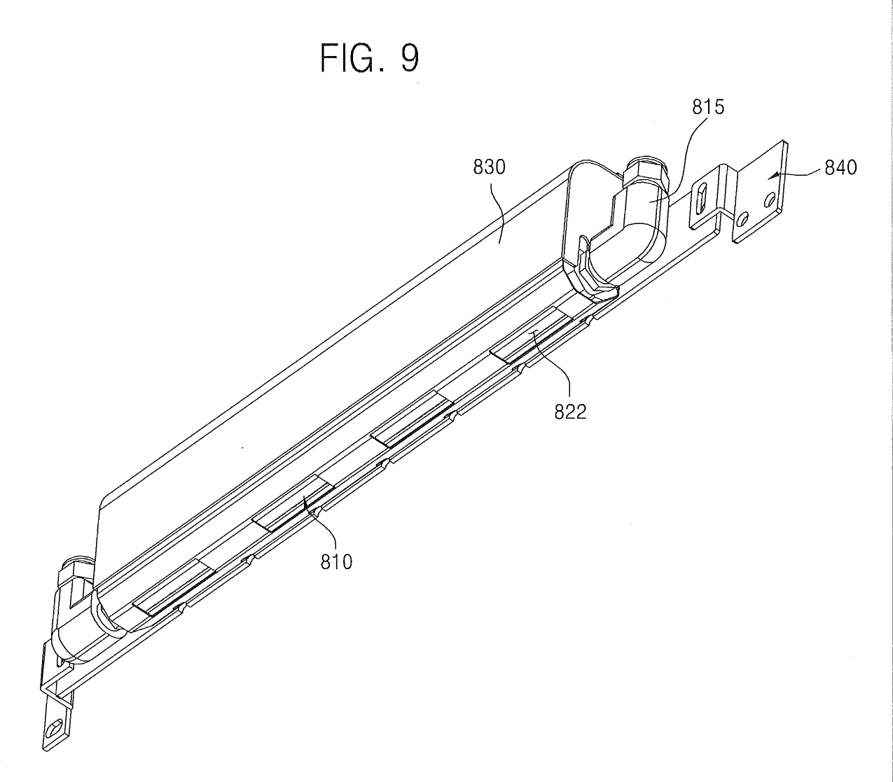

The Coanda suction dust collector 800 according to some embodiments includes a blow portion 810 for blowing compressed air to the outside, a cover 820 where a plurality of through holes 822 (FIG. 9) are formed separated a predetermined distance from each other, a collection unit 830 for collecting foreign materials sucked from the test tray 10, and a support portion 840 coupled to the main body 100 of the test handler and supporting the constituent elements.

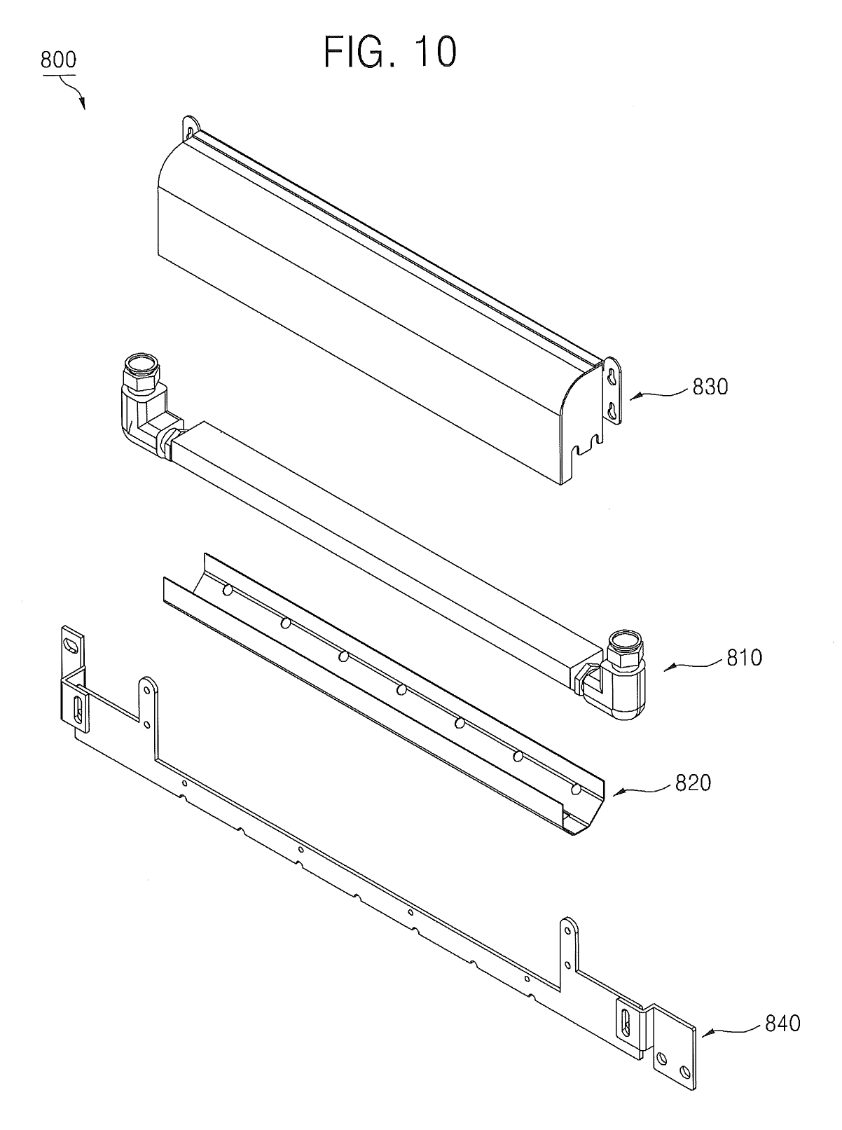

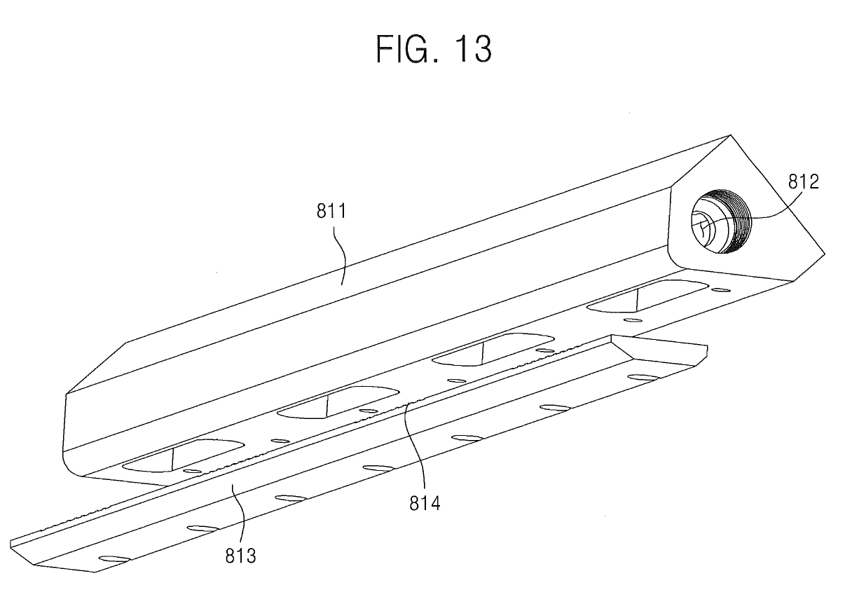

As illustrated in detail in FIGS. 10, 12, and 13, the blow portion 810 includes a first blow body 811, a second blow body 813, and an air supply pipe 815 (refer to FIG. 9). A main air flow path 812 is formed in the first blow body 811. The air supply pipe 815 is coupled to the first blow body 811 and connected to the main air flow path 812. A sunken portion 814 (FIG. 13) is formed in the second blow body 813 by being sunken from a surface to a predetermined depth. Thus, when the first blow body 811 and the second blow body 813 are coupled to each other, the exit air path 816 of FIG. 12 is formed therebetween.

As such, when compressed air is supplied through the air supply pipe 815, air flowing along the main air flow path 812 of the first blow body 811 is exhausted along the exit air path 816 of FIG. 12. The air exhausted along the exit air path 816 flows along the inclined surface A. Accordingly, the surrounding air under the Coanda suction dust collector 800 flows in a direction indicated by the arrow 3 of FIG. 11. As a result, vacuum is generated in an area around the test tray 10 disposed under the Coanda suction dust collector 800 so that the foreign materials existing in the insert 20 of the test tray 10 may be sucked.

The through holes 822 are formed in the cover 820 that is arranged under the Coanda suction dust collector 800. Foreign materials are sucked through the through holes 822. Thus, the separation distance between the through holes 822 may be set in some embodiments to correspond to the distance between the inserts 20 that are installed on the test tray 10.

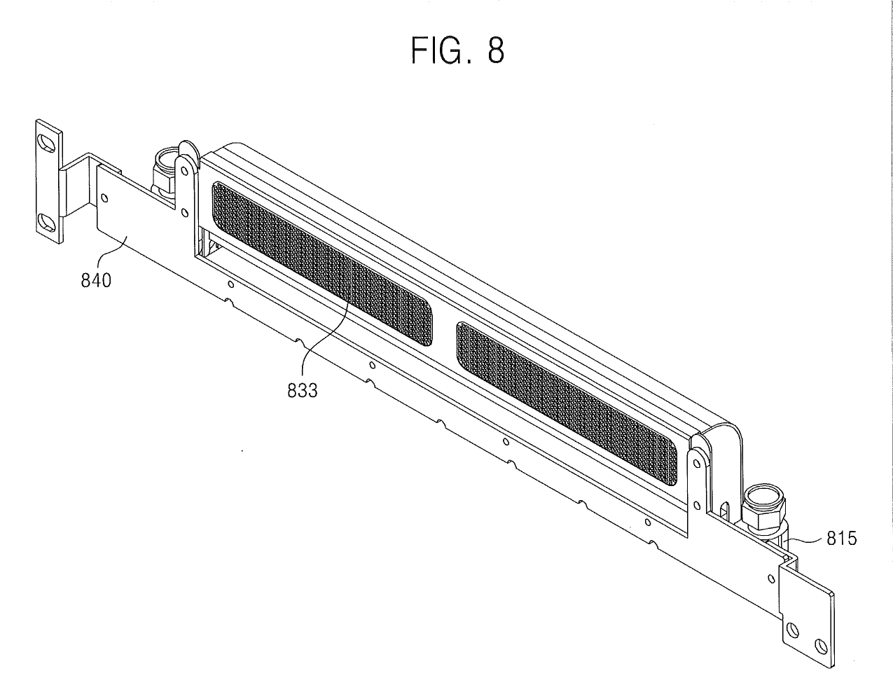

The collection unit 830 for collecting foreign materials sucked from the insert 20 of the test tray 10 in some embodiments includes a collection body 835, a collection basket 831, and a filter portion 833 (FIGS. 8 and 11).

The collection basket 831 is shown coupled to the collection body 835 in FIG, 11 and includes an accommodation space where the sucked foreign materials are stored.

The filter portion 833 is installed at a portion where the air sucked into the Coanda suction dust collector 800 is exhausted, and filters dust and exhausts cleaned air to the outside.

As described above, as the Coanda suction dust collector 800 is provided between the loader stage 510 and the unloader stage 520, foreign materials may be self-cleared as the test tray 10 circulating between the loader stage 510 and the unloader stage 520 for each cycle. Accordingly, the insert 20 of the test tray 10 may be cleaned without pause of a process so that test yield may be improved due to the stable test contact, compared to the conventional technology.

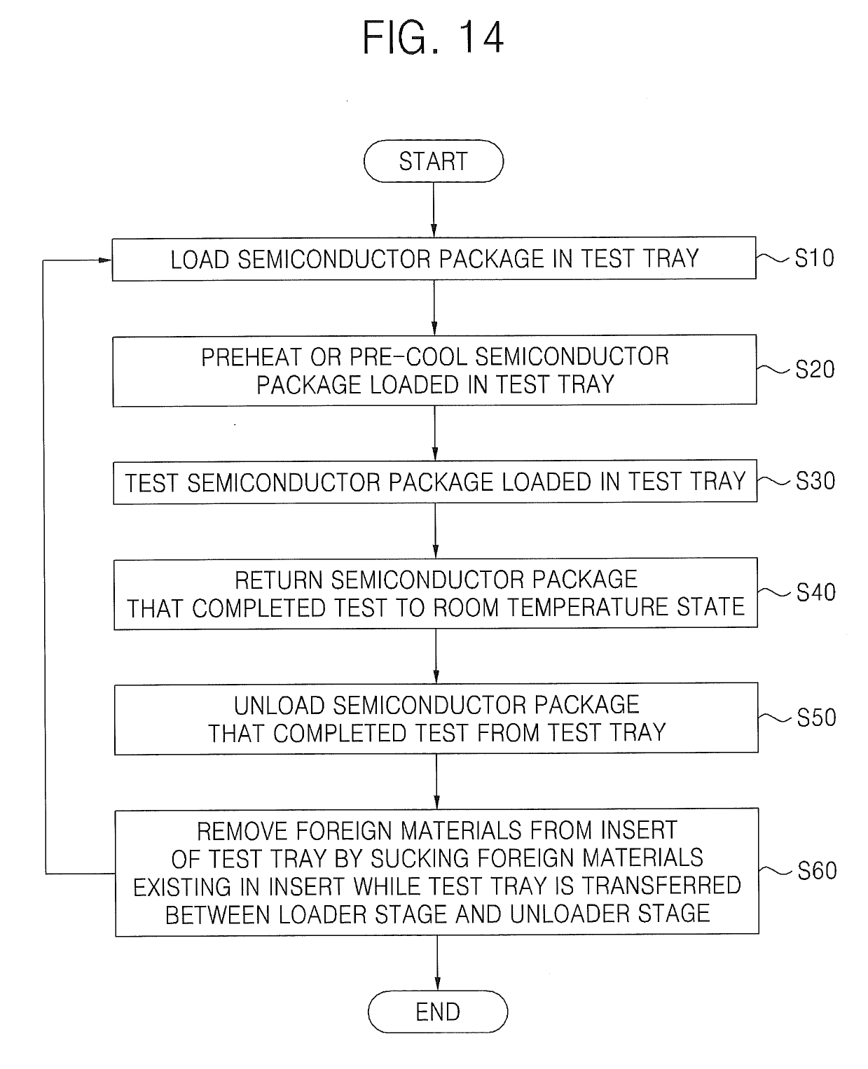

A method of testing a semiconductor package using a test handler for a semiconductor package according to some embodiments of the present inventive concept will be described below in detail with reference to FIGS. 1-13 and 14.

A customer tray loaded in the loading stocker by the transfer arm is transferred to the loading side set plate 610. The semiconductor packages on the customer tray are precised (oriented/aligned) by the loader Cartesian robot 620 in the preciser 530 to be accurately matched with the position in the test tray 10, and are loaded in the test tray 10 (S10). The test tray 10, loaded with the semiconductor packages, is transferred to the soak chamber 200 and heated or cooled at a temperature that is a test condition (S20). Then, the test tray 10 is transferred to the test chamber 300.

A test is performed in the test chamber 300 after the semiconductor packages in the test tray 10 are connected to the test socket (S30). The test tray 10 that completed a test is transferred to the exit chamber 400. While passing through the exit chamber 400, the test tray 10 is returned to a room temperature state (S40) and classified into grades according to a test result by the unloader Cartesian robot 720. The semiconductor packages in the test tray 10 that have completed a test are moved to a customer tray located at the unloading side set plate 710 (S50). When an empty customer tray located at the unloading side set plate 710 is fully filled with the semiconductor packages, the customer tray may be transferred to and loaded in the unloading stocker for each grade by the transfer arm. Then, the transfer arm may transfer a new empty customer tray to the unloading side set plate 710.

While being transferred from the unloader stage 520 to the loader stage 510, the test tray 10 exiting from the exit chamber 400 is cleaned by the Coanda suction dust collector 800 according some embodiments (S60). That is, when the test tray 10 is transferred from the unloader stage 520 to the loader stage 510, the Coanda suction dust collector 800 sucks foreign materials existing in the insert 20 of the test tray 10 so that the foreign materials may be automatically removed without an additional off flow path stoppage related operation. The test tray 10 that is cleaned is transferred to the loader stage 510, loaded with new semiconductor packages to be tested, and transferred to the soak chamber 200 and to the test chamber 300, to thus perform a test. As a new semiconductor package to be tested is loaded in the insert 20 of the test tray 10 after the insert 20 is cleaned, test contact may become superior and test yield may be improved.

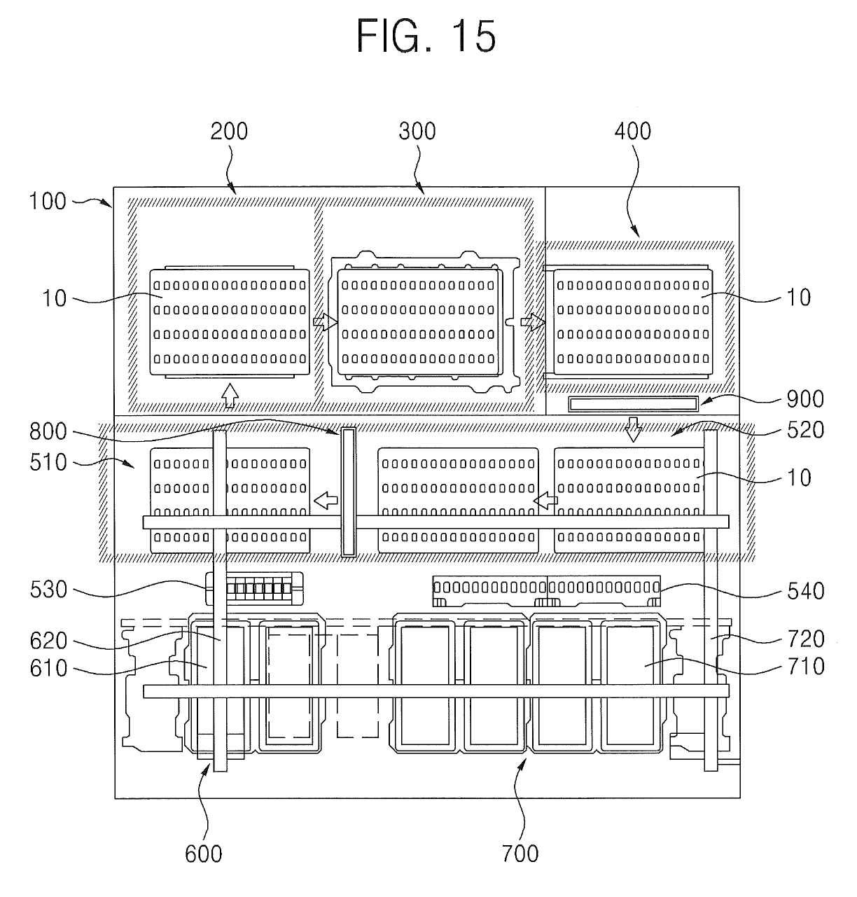

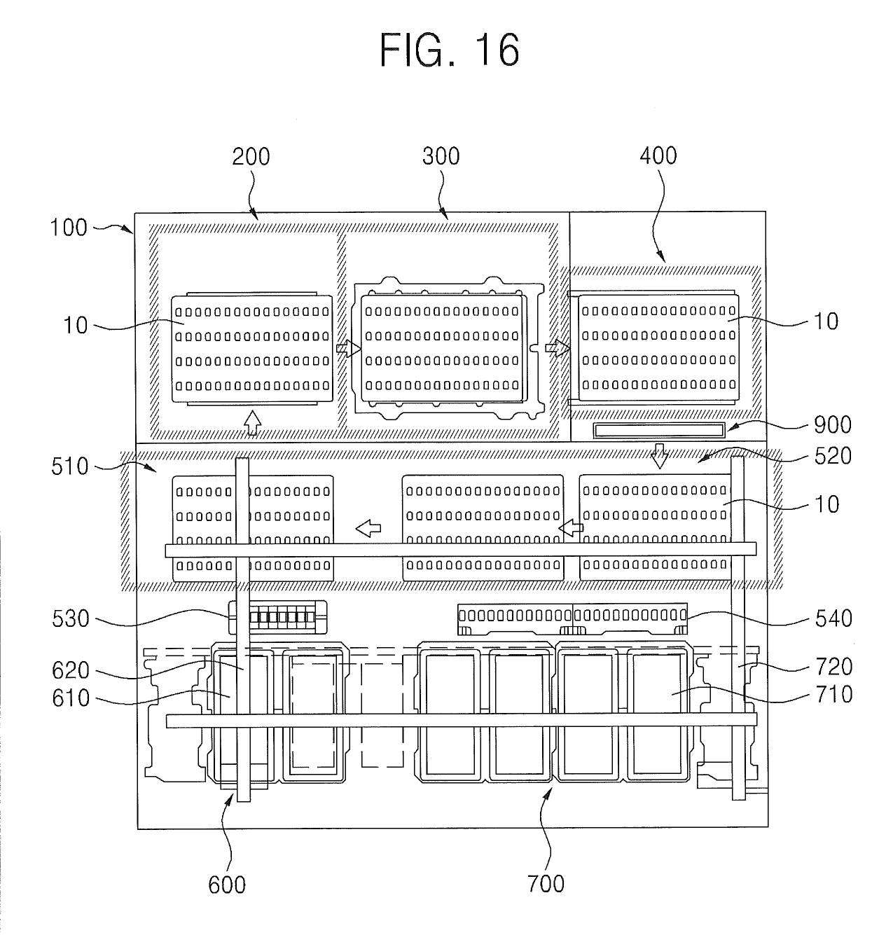

FIG. 15 is a schematic plan view of a test handler for a semiconductor package, according to other embodiments. FIG. 16 is a schematic plan view of a test handler for a semiconductor package, according to yet other embodiments.

Referring to FIG. 15, the test handler for a semiconductor package according to some embodiments includes a test tray cleaning unit including a dust collector 800 for removing foreign materials from the insert 20 of the test tray 10 and an ionizer 900. That is, while in the above-described embodiments only a dust collector is shown, the test handler of the embodiments of FIG. 15 further include the ionizer 900.

The ionizer 900 blows air to limit or even prevent generation of static electricity due to friction between the semiconductor packages loaded in the test tray 10 and the insert 20 of the test tray 10. In the illustrated embodiments, the ionizer 900 is provided on a path along which the test tray 10 is transferred from the exit chamber 400 to the unloader stage 520. Accordingly, the semiconductor package that completed a test may be smoothly moved from the test tray 10 to a customer tray.

Referring to FIG. 16, in the test handler for a semiconductor package according to yet other embodiments, the ionizer 900 is also employed as a test tray cleaning unit. As seen in FIG. 16, the ionizer 900 is provided on a path along which the test tray 10 is transferred from the exit chamber 400 to the unloader stage 520. As such, the test tray cleaning unit in the embodiments of FIG. 16, like the earlier described embodiments, is proximate the loader stage 510.

As described above, according to the present inventive concept, the foreign materials existing in the test tray may be removed during the operation of the test handler. Also, as the foreign materials existing in the test tray are removed, stable test contact may be facilitated so that test yield and productivity may be improved.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

1. A test handler for a semiconductor package, the test handler comprising:
a loader unit that is configured to transfer the semiconductor package to a test tray;
a test chamber that is configured to test the semiconductor package loaded in the test tray;
an unloader unit that is configured to remove the tested semiconductor package from the test tray;
a loader stage that is configured to convey the test tray from the unloader unit to the loader unit; and
a test tray cleaning unit proximate the loader stage that is configured to clean the test tray while it is being conveyed from the unloader unit to the loader unit.

2. The test handler of claim 1, wherein the test tray cleaning unit comprises a suction unit that pulls foreign materials from the test tray when the test tray is proximate the suction unit while being conveyed from the unloader unit to the loader unit.

3. The test handler of claim 2, wherein the suction unit comprises a Coanda suction dust collector.

4. The test handler of claim 3, wherein the Coanda suction dust collector comprises:
a compressed air inlet configured to be coupled to a compressed air source;
a suction inlet positioned proximate the test tray when the test tray is proximate the test tray cleaning unit; and
an air flow path having a start end coupled to the compressed air source by the compressed air inlet and coupled to the suction inlet and an opposite, exit end, wherein the air flow path is configured to provide an air flow rate at the exit end exceeding an air flow rate of compressed air from the compressed air source at the start end using the Coanda effect.

5. The test handler of claim 4, wherein the air flow rate at the exit end is at least twenty times the air flow rate of compressed air from the compressed air source at the start end to provide a suction air flow rate of at least nineteen times the air flow rate of compressed air from the compressed air source at the start end through the suction inlet.

6. The test handler of claim 4, wherein the Coanda suction dust collector further comprises:
a collection body configured to collect foreign materials dropped from air passing through the air flow path; and
a filter portion at the exit end of the air flow path configured to remove foreign materials from air passing through the air flow path that are not collected in the collection body.

7. The test handler of claim 6, wherein the test handler further comprises an ionizer proximate the loader stage that is configured to limit generation of static electricity between the semiconductor package and the test tray when the semiconductor package is in the test tray.

8-9. (canceled)

10. The test handler of claim 1, wherein the test tray cleaning unit comprises an ionizer.

11. The test handler of claim 1, further comprising:
a soak chamber proximate the test chamber that is configured to bring the temperature of the test tray to a first temperature before the test tray is conveyed to the test chamber; and
an exit chamber proximate the test chamber that is configured to bring the test tray to a second temperature after the test tray is conveyed from the test chamber and before the test tray is conveyed from the unloader unit to the loader unit by the loader stage, wherein the loader stage is configured to receive the test tray from the exit chamber and to convey the test tray to the soak chamber.

12. A method of testing a semiconductor package, comprising:
unloading tested semiconductor packages from a test tray after the test tray is conveyed from a test chamber;
conveying the unloaded test tray to a loader unit;
automatically cleaning the unloaded test tray while it is being conveyed to the loader unit; and
loading the cleaned test tray with semiconductor packages to be tested in the test chamber after the cleaned test tray is conveyed to the loader unit.

13. The method of claim 12, wherein automatically cleaning the unloaded test tray comprises automatically cleaning the unloaded test tray using a Coanda suction dust collector that pulls foreign materials from the test tray when the test tray is proximate the Coanda suction dust collector while being conveyed to the loader unit.

14. A test handler for a semiconductor package, the test handler comprising:
a main body;
a test chamber which is provided in the main body and tests a semiconductor package loaded in a test tray; and
a test tray cleaning unit which is provided in the main body and cleans the test tray entering the test chamber or exiting from the test chamber.

15. The test handler of claim 14, wherein the test tray cleaning unit is provided close to at least one of areas of a movement path of the test tray that circulates for entering or exiting from the test chamber.

16. The test handler of claim 15, further comprising:
a soak chamber which is arranged close to the test chamber and preheats or pre-cools the semiconductor package; and
an exit chamber which is arranged close to the test chamber and returns the semiconductor package to a room temperature state,
wherein the test tray cleaning unit is arranged between a loader stage where the test tray is located before entering the soak chamber and an unloader stage where the test tray is located after exiting from the exit chamber and before being transferred to the loader stage.

17. The test handler of claim 14, wherein the test tray cleaning unit is a suction dust collector that sucks foreign materials existing in an insert of the test tray.

18. The test handler of claim 17, wherein the test tray cleaning unit is a Coanda suction dust collector that sucks foreign materials existing in an insert of the test tray by utilizing a Coanda effect in which a fluid flows in a direction in which the least amount of energy is consumed.

19. The test handler of claim 18, wherein the Coanda suction dust collector comprises:
a blow portion which blows air to the outside;
a cover which is coupled to the blow portion and includes a plurality of through holes formed therein;
a collection portion which collects foreign materials sucked from the test tray; and
a support portion which supports the blow portion, the cover, and the collection portion.

20. The test handler of claim 19, wherein the blow portion comprises:
a first blow body in which a main air path is formed;
a second blow body which is coupled to the first blow body and forms an exit air path; and
an air supply pipe which is coupled to the first blow body and supplies air to the main air path.

21. The test handler of claim 19, wherein the collection portion comprises:
a collection body;
a collection basket which is coupled to the collection body and forms an accommodation space for accommodating foreign materials; and
a filter portion which is coupled to the collection body and filters exiting air.

22. The test handler of claim 17, further comprising an ionizer which is coupled to the main body between the exiting chamber and the loader stage and blows air to prevent generation of static electricity due to friction between the semiconductor package and the insert of the test tray.

23-30. (canceled)
